(19) United States
(12) Patent Application Publication
(10) Pub. No.: US 2026/0039256 A1
(43) Pub. Date: Feb. 5, 2026

(54) RUGGEDNESS PROTECTION FOR RF MODULE

(71) Applicant: Qorvo US, Inc., Greensboro, NC (US)

(72) Inventors: Søren Deleuran Laursen, Vestbjerg (DK); Mathias Zacho Vestergaard, Terndrup (DK)

(21) Appl. No.: 18/995,828

(22) PCT Filed: Jun. 6, 2023
(86) PCT No.: PCT/US2023/024558

§ 371 Date: Jan. 16, 2025

Related U.S. Application Data
(60) Provisional application No. 63/390,447, filed on Jul. 19, 2022.
(60) Provisional application No. 63/480,212, filed on Jan. 17, 2023.

(51) Int. Cl. H03F 1/52; H03F 3/24

(52) U.S. Cl. CPC H03F 1/523; H03F 3/245; H03F 2200/171; H03F 2200/451; H03F 2200/465

(57) ABSTRACT

The present disclosure relates to a radio frequency (RF) module with a protection structure for enhanced ruggedness and reliability. The disclosed RF module includes a power amplifier (PA), a bias circuit configured to provide a direct current (DC) supply to the PA, and a protection structure coupled between the PA and the bias circuit. Herein, the protection structure is configured to generate a detector voltage by sensing reverse power reflected from an antenna back to at least the PA. The protection structure is configured to control the bias circuit to reduce the DC supply to the PA based on a comparison result between the detector voltage and a threshold voltage.

### RELATED APPLICATIONS

This application claims the benefit of provisional patent application Ser. No. 63/390,447, filed on Jul. 19, 2022, and provisional patent application Ser. No. 63/480,212, filed on Jan. 17, 2023, the disclosures of which are hereby incorporated herein by reference in their entireties.

### FIELD OF THE DISCLOSURE

The present disclosure relates to a radio frequency (RF) module with a protection structure for enhanced ruggedness and reliability.

### BACKGROUND

Ruggedness and reliability of a radio frequency (RF) module are some of the most important characteristics of the RF module. One way of testing ruggedness of the RF module is to apply a large Voltage Standing Wave Ratio (VSWR) at an antenna port of the RF module and drive a power amplifier (PA) inside the RF module with a high input power and supply voltage. This test will stress both the PA and any component between the PA and the antenna port. A Surface Acoustic Wave (SAW) filter between the PA and the antenna port, for instance, is one of the most valuable components that needs ruggedness protection.

Accordingly, there is a need for improved RF module designs to enhance the ruggedness and reliability of the RF module so as to accommodate high VSWR situations without sacrificing module performance in low VSWR situations. In particular, the improved RF module designs are needed to provide protection for the PA(s) and the component(s) between the PA and the antenna port within the RF module under the high VSWR situations.

### SUMMARY

The present disclosure relates to a radio frequency (RF) module with a protection structure for enhanced ruggedness and reliability. The disclosed RF module includes a first power amplifier (PA), a first bias circuit configured to provide a first direct current (DC) supply to the first PA, and a protection structure coupled between the first PA and the first bias circuit. Herein, the protection structure is configured to generate a detector voltage by sensing reverse power reflected from an antenna back to at least the first PA. The protection structure is configured to control the first bias circuit to reduce the first DC supply to the first PA based on a comparison result between the detector voltage and a threshold voltage.

In one embodiment of the disclosed RF module, the threshold voltage indicates a maximum value that the reverse power is allowed.

In one embodiment of the disclosed RF module, the protection structure includes a directional coupler, a reverse power detector, a protection operational amplifier (Opamp), and a first protection controller. A combination of the directional coupler and the reverse power detector is configured to sense the reverse power reflected from the antenna back to the first PA. Herein, the detector voltage is an output of the reverse power detector. The protection Opamp is configured to compare the detector voltage and the threshold voltage. The first protection controller is configured to control the first bias circuit to reduce the first DC supply to the first PA based on the comparison result.

In one embodiment of the disclosed RF module, the first protection controller is implemented by one or more Field Effect Transistors (FETs) and configured to control the first bias circuit by injecting current into the first bias circuit.

In one embodiment of the disclosed RF module, the protection structure is configured to generate the detector voltage further by sensing forward power delivered to the antenna from at least the first PA. Herein, the threshold voltage indicates a maximum value that a sum of the reverse power and the forward power is allowed.

In one embodiment of the disclosed RF module, the protection structure includes the directional coupler, a forward power detector, the reverse power detector, the protection Opamp, and the first protection controller. A combination of the directional coupler, the forward power detector, and the reverse power detector is configured to sense both the forward power and the reverse power. Herein, the detector voltage is a sum of an output of the forward power detector and the output of the reverse power detector. The protection Opamp is configured to compare the detector voltage and the threshold voltage. The first protection controller is configured to control the first bias circuit to reduce the first DC supply to the first PA based on the comparison result.

In one embodiment of the disclosed RF module, the forward power detector and the reverse power detector have different detection gains.

In one embodiment of the disclosed RF module, the reverse power detector has a greater detection gain than the forward power detector.

In one embodiment of the disclosed RF module, the forward power detector and the reverse power detector have a same detection gain.

According to one embodiment, the disclosed RF module further includes a filter coupled between the first PA and the antenna.

According to one embodiment, the disclosed RF module further includes a second PA and a second bias circuit configured to provide a second DC supply to the second PA. Herein, the protection structure is coupled between the second PA and the second bias circuit.

In one embodiment of the disclosed RF module, the protection structure is configured to generate the detector voltage by sensing the reverse power reflected from the antenna back to both the first PA and the second PA. The protection structure is configured to control the second bias circuit to reduce a second DC supply to the second PA based on the comparison result between the detector voltage and the threshold voltage.

In one embodiment of the disclosed RF module, the protection structure includes the directional coupler, the reverse power detector, the protection Opamp, the first protection controller, and a second protection controller. A combination of the directional coupler and the reverse power detector is configured to sense the reverse power reflected from the antenna back to both the first PA and the second PA. The detector voltage is the output of the reverse power detector. The protection Opamp is configured to compare the detector voltage and the threshold voltage. The first protection controller is configured to control the first bias circuit to reduce the first DC supply to the first PA based on the comparison result, and the second protection controller is configured to control the second bias circuit to reduce the second DC supply to the second PA based on the comparison result. Herein, the threshold voltage indicates the maximum value that the reverse power is allowed.

In one embodiment of the disclosed RF module, the first protection controller is implemented by one or more FETs and configured to control the first bias circuit by injecting current into the first bias circuit. The second protection controller is implemented by one or more FETs and configured to control the second bias circuit by injecting current into the second bias circuit.

In one embodiment of the disclosed RF module, the protection structure is configured to generate the detector voltage further by sensing forward power delivered to the antenna from both the first PA and the second PA.

In one embodiment of the disclosed RF module, the protection structure includes the directional coupler, the reverse power detector, the forward power detector, the protection Opamp, the first protection controller, and the second protection controller. A combination of the directional coupler, the forward power detector, and the reverse power detector is configured to sense the forward power delivered to the antenna from both the first PA and the second PA and the reverse power reflected from the antenna back to both the first PA and the second PA. The detector voltage is a sum of the output of the forward power detector and the output of the reverse power detector. The protection Opamp is configured to compare the detector voltage and the threshold voltage. The first protection controller is configured to control the first bias circuit to reduce the first DC supply to the first PA based on the comparison result, and the second protection controller is configured to control the second bias circuit to reduce the second DC supply to the second PA based on the comparison result. Herein, the threshold voltage indicates a maximum value that a sum of the reverse power and the forward power is allowed.

According to one embodiment, the disclosed RF module further includes a first filter coupled between the first PA and the antenna, and a second filter coupled between the second PA and the antenna.

In another aspect, any of the foregoing aspects individually or together, and/or various separate aspects and features as described herein, May be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 shows an exemplary radio frequency (RF) module with enhanced ruggedness and reliability according to some embodiments of the present disclosure.

FIG. 2 shows an alternative RF module according to some embodiments of the present disclosure.

FIG. 3 shows an exemplary RF module with multiple power amplifiers according to some embodiments of the present disclosure.

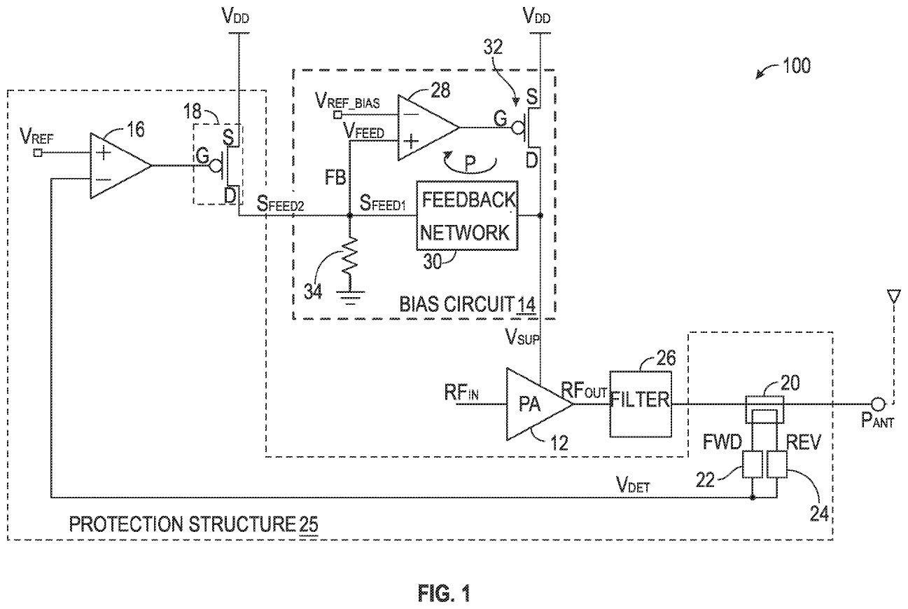

It will be understood that for clear illustrations, FIGS. 1-3 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to a radio frequency (RF) module with a protection structure for enhanced ruggedness and reliability. FIG. 1 shows an exemplary RF module 100 according to some embodiments of the present disclosure. For the purpose of this illustration, the exemplary RF module 100 includes a power amplifier (PA) 12, a bias circuit 14, a protection operational amplifier (Opamp) 16, a protection controller 18, a directional coupler 20, a forward (FWD) power detector 22, and a reverse (REV) power detector 24. Herein, the protection Opamp 16, the protection controller 18, the directional coupler 20, the FWD power detector 22, and the REV power detector 24 form a protection structure 25, which is configured to control the bias circuit 14 to reduce a direct current (DC) supply (e.g., a DC voltage supply or a DC current supply) to the PA 12. In different applications, the RF module 100 may include more PAS 12, more bias circuits 14, and correspondingly more protection controllers 18 in the protection structure 25.

In detail, the PA 12, with the DC supply provided by the bias circuit 14, is configured to receive a RF input signal RF_{IN} and provide an output RF signal RF_{OUT} towards an antenna port P_{ANT}. Typically, a lower DC supply applied to the PA 12 will cause a reduction in gain of the PA 12 and thus a reduction in power of the output RF signal RF_{OUT}. With different implementations of the PA 12, the DC supply from the bias circuit 14 may be applied for PA base-bias or PA collector-bias. In some applications, the PA 12 may be followed by a filter 26 (e.g., a band-pass filter), which is configured to remove noise portions of the output RF signal RF_{OUT} before the output RF signal RF_{OUT} is delivered to the antenna port P_{ANT}. The filter 26 may be a Surface Acoustic Wave (SAW) filter. In some applications, there might be a switch between the PA 12 and the filter 26 (not shown).

The protection structure 25 is coupled between the PA 12/the filter 26

and the bias 14. In the protection structure 25, the directional coupler 20 is coupled between the filter 26 and the antenna port P_{ANT} or between the PA 12 and the antenna port P_{ANT} if the filter 26 does not exist. In some applications, there might be a switch between the filter 26 and the directional coupler 20 or between the PA 12 and the directional coupler 20 if the filter 26 does not exist (not shown). The output RF signal RF_{OUT} from the PA 12 (followed or not followed by the filter 26) is sensed by a combination of the directional coupler 20, the FWD power detector 22, and the REV power detector 24. The directional coupler 20 is configured to distinguish between forward power (from the PA 12 to the antenna ANT) and reverse power (back to the PA 12 from the antenna ANT) in the output RF signal RF_{OUT}. The FWA power detector 22 is configured to detect the forward power and the REV power detector 24 is configured to detect the reverse power.

In an ideal case (i.e., the RF module 100 has a matching 50 Ω impedance at the antenna port P_{ANT}), an output of the FWD power detector 22 indicates actual forward power delivered from the PA 12 to the antenna and transmitted by the antenna, while an output of the REV power detector 24 is zero. However, in practice, it is challenging to always maintain the matching 50 Ω impedance for the RF module 100 at the antenna port P_{ANT} for broadband and/or high-power. If the impedance for the RF module 100 at the antenna port P_{ANT} is different from the impedance of the antenna ANT (i.e., a condition that a Voltage Standing Wave Ratio, VSWR, is larger than 1:1), a portion of the delivered forward power to the antenna will be reflected back to the PA 12 and detected by the REV power detector 24, and the output of the REV power detector 24 is non-zero. In other words, non-zero output of the REV power detector 24 indicates an impedance mismatch between the impedance for the RF module 100 at the antenna port P_{ANT} and the impedance of the antenna ANT.

An extreme case of infinite VSWR (i.e., an extreme mismatch between the impedance for the RF module 100 at the antenna port P_{ANT} and the impedance of the antenna ANT) may cause a 100% reflection back to the PA 12. The large portion of reflection will cause an efficiency issue of the RF module and may put unacceptable stress (e.g., heat dissipation challenges, voltage breakdown limits) on the PA 12 and components between the PA 12 and the antenna port P_{ANT} (e.g., the filter 26). As such, limiting the reverse power reflected from the antenna back to the PA 12 is necessary, especially for the high VSWR scenarios. Furthermore, in some cases (e.g., especially the low VSWR scenarios when the reverse power is neglectable, like 1.5:1>VSWR>=1:1), the forward power delivered from the PA to the antenna may also need to be limited to an accurate value.

In one embodiment, the outputs from the FWD power detector 22 and the REV power detector 24 are added to form a detector voltage V_{DET} that is fed back to the protection Opamp 16. The protection Opamp 16 is configured to compare the detector voltage V_{DET} to a threshold voltage V_{REF} (e.g., the threshold voltage V_{REF} is applied at a positive input of the protection Opamp 16, and the detector voltage V_{DET} is applied at a negative input of the protection Opamp 16). Herein, the threshold voltage V_{REF} for the protection Opamp 16 indicates a maximum value that a combination of the reverse power and the forward power is allowed.

Based on the comparison result from the protection Opamp 16, the protection controller 18 is configured to control the bias circuit 14. The protection controller 18 may be implemented by one or more Field Effect Transistor (FET) switches, like a p-channel FET (PFET) or a n-channel FET (NFET, not shown). In different applications, the protection controller 18 may have different implementations, but is always capable of being controlled by the comparison result of the protection Opamp 16. The protection controller 18 may be implemented by any active element or combinations thereof that are capable of creating an output current when the detector voltage V_{DET} is in one state (e.g., when the detector voltage V_{DET} is not smaller than the threshold voltage V_{REF}, such that the protection controller 18 is turned on) and creating no output current when the detector voltage V_{DET} is in another state (e.g., when the detector voltage V_{DET} is smaller than the threshold voltage V_{REF}, such that the protection controller 18 is turned off).

The bias circuit 14 has an internal feedback path P. For the purpose of this illustration, the bias circuit 14 includes a bias Opamp 28, a bias feedback network 30, a bias output FET 32, and a bias resistor 34. The bias Opamp 28 is configured to compare a bias threshold voltage V_{REF_BIAS} with a feedback voltage V_{FEED} at a connection node FB (e.g., the bias threshold voltage V_{REF_BIAS} is applied at a negative input of the bias Opamp 28, and the feedback voltage V_{FEED} is applied at a positive input of the bias Opamp 28). The bias threshold voltage V_{REF_BIAS} for the bias Opamp 28 indicates a voltage limit for the antenna port P_{ANT} imposed by the system 100. Based on the comparison result from the bias Opamp 28, the bias output FET 32 turns on or off to change the current/voltage applied to the PA 12 so as to change the gain of the PA 12 and the output RF signal RF_{OUT} of the PA 12. The bias feedback network 30 is coupled between the bias output FET 32 and the connection node FB to form the internal feedback path P. The bias resistor 34 is coupled between the connection node FB and ground. In addition, an output of the protection structure 25 (i.e., an output of the protection controller 18 of the protection structure 25) is also coupled to the connection node FB. Therefore, the feedback voltage V_{FEED} at the connection node FB is based on a first feedback signal S_{FEED1} provided by the bias feedback network 30 and a second feedback signal S_{FEED2} provided by the protection controller 18 of the protection structure 25. In different applications, the bias circuit 14 may be implemented with different components and/or with a different layout. Any type of bias circuit can be used if it has a variable output that is capable of being controlled by the protection controller 18. If one bias circuit has an internal feedback loop, a preferred connection is as shown in FIG. 1.

For a non-limited example, the protection controller 18 is a PFET, which has a source S coupled to a DC power V_{DD}, a gate G coupled to an output of the protection Opamp 16, and a drain D coupled to the connection node FB. The bias output FET 32 is also a PFET, which has a source S coupled to the DC power V_{DD}, a gate G coupled to an output of the bias Opamp 28, and a drain D coupled to the bias feedback network 30 and providing a DC supply voltage V_{SUP} to the PA 12. Herein, when the detector voltage V_{DET} being fed back to the protection Opamp 16 is smaller than the threshold voltage V_{REF}, the PFET/protection controller 18 turns off, and therefore, the protection structure 25 does not change operations of the bias circuit 14 (i.e., the second feedback signal S_{FEED2} provided by the protection controller 18 is zero). In the bias circuit 14, current flows through the bias output PFET 32, which generates the DC supply voltage V_{SUP} to the PA 12 and generates the feedback voltage V_{FEED} at the connection node FB through the bias feedback network 30 (herein, V_{FEED}=S_{FEED1}). Once the feedback voltage V_{FEED} is equal to the bias threshold voltage V_{REF_BIAS}, the bias circuit achieves a steady-state condition and provides a steady current/voltage to the PA 12.

Once the detector voltage V_{DET} being fed back to the protection Opamp 16 is not smaller than the threshold voltage V_{REF}, the protection structure 25 is configured to control the bias circuit 14 to decrease the DC supply voltage V_{SUP} to the PA 12. As such, the gain of the PA 12 decreases, the output RF signal RF_{OUT} of the PA 12 decreases, and the detector voltage V_{DET} decreases accordingly. In particular, when the detector voltage V_{DET} being fed back to the protection Opamp 16 is larger than the threshold voltage V_{REF}, the PFET/protection controller 18 turns on, such that current (feedback signal S_{FEED2}) from the drain D of the PFET/protection controller 18 injects into the bias circuit 14 at the connection node FB. As such, the feedback voltage V_{FEED} at the connection node FB increases, an output of the bias Opamp 28 increases, and thus the current flowing through the bias output FET 32 (i.e., the current flowing out of the drain D of the bias output FET 32) and the DC supply voltage V_{SUP} provided to the PA 12 decreases. Lowering the DC supply voltage V_{SUP} will lead to the gain decrease of the PA 12, and the output power (e.g., both the forward and reverse power) of the PA 12 and the detector voltage V_{DET} will also decrease. In consequence, the current (the feedback signal S_{FEED2}) from the PFET/protection controller 18 into the connection node FB will decrease. In addition, lowering the DC supply voltage V_{SUP} will also decrease the first feedback signal S_{FEED1} out of the bias feedback network 30. As a result, the feedback voltage V_{FEED} at the connection node FB is reduced to re-approach the bias threshold voltage V_{REF_BIAS} of the bias Opamp 28, and the bias circuit 14 and the RF module 100 achieve equilibrium.

Herein, due to large gains in the protection Opamp 16 and the PFET/protection controller 18, the protection Opamp 16 and the PFET/protection controller 18 are sensitive to the detector voltage V_{DET} exceeding the threshold voltage V_{REF}. Once the detector voltage V_{DET} slightly exceeds the threshold voltage V_{REF}, the protection structure 25 is in action. As such, the detector voltage V_{DET} is effectively prevented from exceeding the threshold voltage V_{REF}. By utilizing the FWD power detector 22 and the REV power detector 24, both the forward power (from the PA 12 to the antenna ANT) and the reverse power (back to the PA 12 from the antenna ANT) can be limited, which will benefit both the high VSWR scenarios and low VSWR scenarios. The threshold voltage V_{REF} for the protection Opamp 16 can be adjusted with frequency variations.

In one embodiment, the FWD power detector 22 and the REV power detector 24 have certain detection gain(s) (e.g., a same detection gain), such that the output from the FWD power detector 22 and the output from the REV power detector 24 have a same weight in the detector voltage V_{DET}. The detection gains in the FWD power detector 22 and the REV power detector 24 are adjustable to allow different behaviors for the protection structure 25. For a non-limiting example, when the REV power detector 24 has a much greater detection gain than the FWD power detector 22, the output from the FWD power detector 22 and the output from the REV power detector 24 will have different weights in the detector voltage V_{DET}, the output from the REV power detector 24 playing a dominant role in the detector voltage V_{DET}.

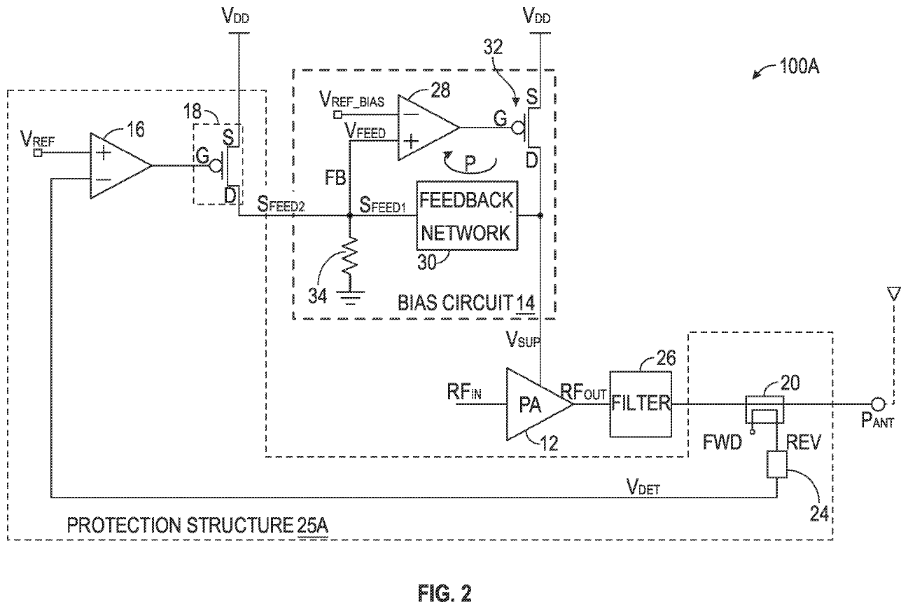

FIG. 2 illustrates an alternative RF module 100A with an alternative protection structure 25A, which is configured to control the bias circuit 14 based only on the reverse power. The alternative RF module 100A, in addition to the alternative protection structure 25A, also includes the PA 12, the bias circuit 14, and the filter 26, and has the same layout as the RF module 100.

Compared to the protection structure 25, the FWD power detector 22 is omitted in the alternative protection structure 25A. In this embodiment, the reverse power (reflected from the antenna ANT back to the PA 12) is sensed by a combination of the directional coupler 20 and the REV power detector 24. The detector voltage V_{DET} being fed back to the protection Opamp 16 is only the output of the REV power detector 24, and only indicates the reverse power. In this embodiment, the threshold voltage V_{REF} for the protection Opamp 16 indicates a maximum value that the reverse power is allowed. Similar to the protection structure 25, when the detector voltage V_{DET} being fed back to the protection Opamp 16 is smaller than the threshold voltage V_{REF}, the protection controller 18 turns off and the alternative protection structure 25 does not change operations of the bias circuit 14. Once the detector voltage V_{DET} being fed back to the protection Opamp 16 is not smaller than the threshold voltage V_{REF}, the alternative protection structure 25A is configured to control the bias circuit 14 to decrease the DC supply voltage V_{SUP} to the PA 12, so as to reduce the output RF signal RF_{OUT} of the PA 12 and the detector voltage V_{DET}.

Due to the large gains in the protection Opamp 16 and the protection controller 18, the protection Opamp 16 and the protection controller 18 are sensitive to the detector voltage V_{DET} exceeding the threshold voltage V_{REF}. Once the detector voltage V_{DET} slightly exceeds the threshold voltage V_{REF}, the alternative protection structure 25A is in action. As such, the detector voltage V_{DET} is effectively prevented from exceeding the threshold voltage V_{REF}. The reverse power back to the PA 12/filter 26 can be effectively limited by the threshold voltage V_{REF}. The threshold voltage V_{REF} for the protection Opamp 16 can be adjusted with frequency variations.

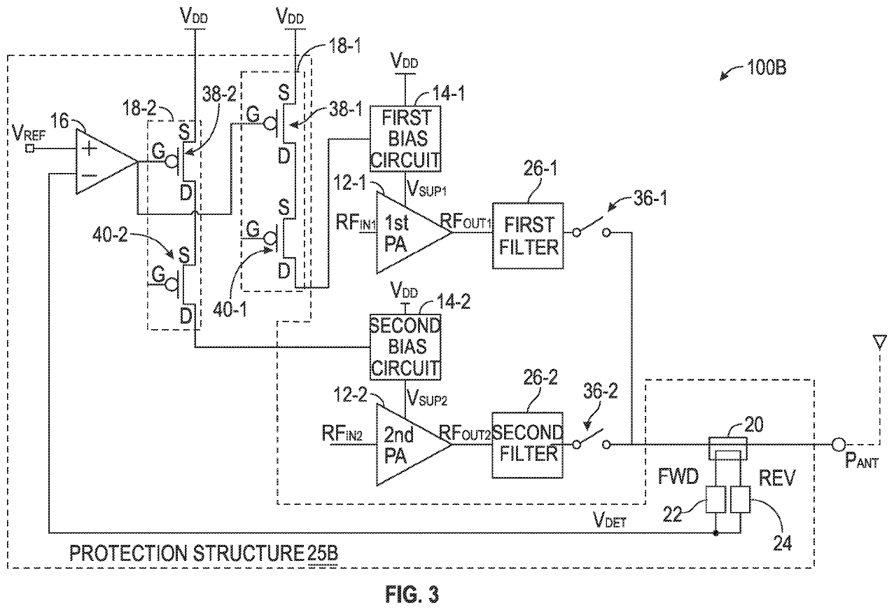

One complete RF module may include more than one PA corresponding to more than one bias circuit, as illustrated in FIG. 3. For the purpose of this illustration, a RF module 100B includes a first PA 12-1, a second PA 12-2, a first bias circuit 14-1, a second bias circuit 14-2, a first filter 26-1, a second filter 26-2, and a protection structure 25B. Herein, the protection structure 25B controls both the first bias circuit 14-1 and the second bias circuit 14-2. The first bias circuit 14-1 is configured to provide a first DC supply (e.g., a DC voltage supply or a DC current supply) to the first PA 12-1, and the second bias circuit 14-2 is configured to provide a second DC supply (e.g., a DC voltage supply or a DC current supply) to the second PA 12-2. The first filter 26-1 is coupled between the first PA 12-1 and the antenna port P_{ANT}, and the second filter 26-2 is coupled between the second PA 12-2 and the antenna port P_{ANT}. In some cases, enable-switches 36 may be applied between the antenna port P_{ANT} and corresponding PAs 12 to connect/disconnect the corresponding PAs 12 to/from the antenna port P_{ANT}, respectively. In one embodiment, a first enable-switch 36-1 is coupled between the first filter 26-1 and the antenna port P_{ANT}, and a second enable-switch 36-2 is coupled between the second filter 26-2 and the antenna port P_{ANT}. In another embodiment, the first enable-switch 36-1 is coupled between the first PA 12-1 and the first filter 26-1, and the second enable-switch 36-2 is coupled between the second PA 12-2 and the second filter 26-2 (not shown).

Corresponding to the two bias circuits 14, the protection structure 25B includes two protection controllers 18 (e.g., a first protection controller 18-1, and a second protection controller 18-2). In addition to the protection controllers 18, the protection structure 25B also includes the protection Opamp 16, the directional coupler 20, the FWD power detector 22, and the REV power detector 24. In the protection structure 25B, the FWD power detector 22 is configured to detect the forward power to the antenna from the first PA 12-1 and/or the second PA 12-2, while the REV power detector 24 is configured to detect the reverse power from the antenna back to the first PA 12-1 and/or the second PA 12-2 (depending on the ON or OFF state of the first enable-switch 36-1 and the ON or OFF state of the second enable-switch 36-2). The outputs from the FWD power detector 22 and the REV power detector 24 are added to form the detector voltage V_{DET} that is fed back to the protection Opamp 16.

The protection Opamp 16 is configured to compare the detector voltage V_{DET} to a threshold voltage V_{REF} (e.g., the threshold voltage V_{REF} is applied at the positive input of the protection Opamp 16, and the detector voltage V_{DET} is applied at the negative input of the protection Opamp 16). Herein, the threshold voltage V_{REF} for the protection Opamp 16 is adjustable. When the FWD and REV power detectors 22 and 24 only detect output power (including both the forward power and the reverse power) of the first PA 12-1, the threshold voltage V_{REF} may indicate a maximum value that the output power of the first PA 12-1 is allowed. When the FWD and REV power detectors 22 and 24 only detect output power (including both the forward power and the reverse power) of the second PA 12-2, the threshold voltage V_{REF} may indicate a maximum value that the output power of the second PA 12-2 is allowed. When the FWD and REV power detectors 22 and 24 detect the output power of both the first PA 12-1 and the second PA 12-2, the threshold voltage V_{REF} may indicate a maximum value that the total output power of both the first PA 12-1 and the second PA 12-2 is allowed.

In some applications, if the forward power detector 22 is omitted in the protection structure 25B (not shown), the detector voltage V_{DET} being fed back to the protection Opamp 16 is the output of the REV power detector 24. In consequence, the threshold voltage V_{REF} for the protection Opamp 16 may indicate a maximum value that the reverse power of the first PA 12-1 is allowed, a maximum value that the reverse power of the second PA 12-2 is allowed, or a maximum value that the total reverse power of both the first PA 12-1 and the second PA 12-2 is allowed.

Each protection controller 18 is coupled between the protection Opamp 16 and a corresponding bias circuit 14, such that each protection controller 18 is configured to control its corresponding bias circuit 14 based on the same comparison result from the protection Opamp 16. In some applications, one switch (not shown) may be employed before or after each protection controller 18, such that the protection structure 25B can be separately disconnected from the first bias circuit 14-1 or the second bias circuit 14-2 if needed.

Each protection controller 18 may have different implementations (e.g., one or more FET switches) for different applications, where each implementation is capable of being controlled by the comparison result of the protection Opamp 16. In this embodiment, the first protection controller 18-1 is implemented by a first upper PFET 38-1 and a first lower PFET 40-1 coupled in series, and the second protection controller 18-2 is implemented by a second upper PFET 38-2 and a second lower PFET 40-2 coupled in series. In detail, a source S of the first upper PFET 38-1 is coupled to the DC power V_{DD}, a gate G of the first upper PFET 38-1 is coupled to the output of the protection Opamp 16, a drain D of the first upper PFET 38-1 is coupled to a source S of the first lower PFET 40-1, a gate G of the first lower PFET 40-1 is coupled to a fixed voltage (not shown, e.g., ground) level to enable the first lower PFET 40-1 to be conducted, and a drain D of the first lower PFET 40-1 is coupled to the first bias circuit 14-1. A source S of the second upper PFET 38-2 is coupled to the DC power V_{DD}, a gate G of the second upper PFET 38-2 is coupled to the output of the protection Opamp 16, a drain D of the second upper PFET 38-2 is coupled to a source S of the second lower PFET 40-2, a gate G of the second lower PFET 40-2 is coupled to a fixed voltage (not shown, e.g., ground) level to enable the second lower PFET 40-2 to be conducted, and a drain D of the second lower PFET 40-2 is coupled to the second bias circuit 14-2.

Each of the first bias circuit 14-1 and the second bias circuit 14-2 may have the same configuration as the bias circuit 14 shown in FIG. 1. As such, when the detector voltage V_{DET} from the detectors 22 and 24 is smaller than the threshold voltage V_{REF}, both the first and second protection controllers 18 turn off, and therefore, the protection structure 25B does not change operations of the first bias circuit 14-1 or the second bias circuit 14-2. Once the detector voltage V_{DET} is no longer smaller than the threshold voltage V_{REF}, both the first and second protection controllers 18 turn on. Current flowing out of the first protection controller 18-1 injects into the first bias circuit 14-1, which causes a first DC supply voltage V_{SUP1} to the first PA 12-1 to decrease. Similarly, current flowing out of the second protection controller 18-2 injects into the second bias circuit 14-2, which causes a second DC supply voltage V_{SUP2} to the second PA 12-1 to decrease. Lowering the first DC supply voltage V_{SUP1} will lead to a gain decrease of the first PA 12-1, while lowering the second DC supply voltage V_{SUP2} will lead to a gain decrease of the second PA 12-2. In consequence, the total output power (i.e., the total forward power and the total reverse power) of the first PA 12-1 and the second PA 12-2 will decrease, and the detector voltage V_{DET} will decrease. Once the detector voltage V_{DET} becomes smaller than the threshold voltage V_{REF}, the protection controllers 18 will be OFF again. The RF module 100B will achieve equilibrium. Herein, the output power (i.e., the forward power and the reverse power) of the first PA 12-1 and/or the output power (i.e., the forward power and the reverse power) of the second PA 12-2 can be effectively limited by the threshold voltage V_{REF} of the protection Opamp 16.

The protection structure 25/25A/25B is based on sensing the forward and/or reverse power of the PA(s) 12 by the directional coupler 20 with the FWD power detector 22 and/or the REV power detector 24, and based on the sensing result, controlling the bias circuit(s) 14 to limit the DC supply to the corresponding PA(s) 12, respectively. As such, the allowed amount of the forward and/or reverse power of the PA(s) 12 is limited.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. A radio frequency (RF) module comprising:
a first power amplifier (PA);
a first bias circuit configured to provide a first direct current (DC) supply to the first PA wherein:
the first bias circuit includes a bias operational amplifier (Opamp) and an internal feedback path providing a feedback voltage as an input of the bias Opamp; and
the first DC supply provided to the first PA is based on a comparison result between the feedback voltage and a bias threshold voltage; and
a protection structure coupled between the first PA and the first bias circuit, wherein:
the protection structure is configured to generate a detector voltage by sensing reverse power reflected from an antenna back to at least the first PA; and
the protection structure includes a first protection controller, which is configured to change the feedback voltage to the bias Opamp by injecting current into the internal feedback path of the first bias circuit based on a comparison result between the detector voltage and a threshold voltage, so as to change the first DC supply to the first PA.

2. The RF module of claim 1 wherein the threshold voltage indicates a maximum value that the reverse power is allowed.

3. The RF module of claim 1 wherein:
the protection structure includes a directional coupler, a reverse power detector, a protection operational amplifier (Opamp), and the first protection controller;
a combination of the directional coupler and the reverse power detector is configured to sense the reverse power reflected from the antenna back to the first PA, wherein the detector voltage is an output of the reverse power detector;
the protection Opamp is configured to compare the detector voltage and the threshold voltage; and
the first protection controller is configured to control the first bias circuit to reduce the first DC supply to the first PA based on the comparison result.

4. The RF module of claim 3 wherein the first protection controller is implemented by one or more Field Effect Transistors (FETs).

5. The RF module of claim 1 wherein the protection structure is configured to generate the detector voltage further by sensing forward power delivered to the antenna from at least the first PA.

6. The RF module of claim 5 wherein the threshold voltage indicates a maximum value that a sum of the reverse power and the forward power is allowed.

7. The RF module of claim 5 wherein:
the protection structure includes a directional coupler, a forward power detector, a reverse power detector, a protection Opamp, and the first protection controller;
a combination of the directional coupler, the forward power detector, and the reverse power detector is configured to sense both the forward power and the reverse power, wherein the detector voltage is a sum of an output of the forward power detector and an output of the reverse power detector;
the protection Opamp is configured to compare the detector voltage and the threshold voltage; and
the first protection controller is configured to control the first bias circuit to reduce the first DC supply to the first PA based on the comparison result.

8. The RF module of claim 7 wherein the forward power detector and the reverse power detector have different detection gains.

9. The RF module of claim 8 wherein the reverse power detector has a greater detection gain than the forward power detector.

10. The RF module of claim 7 wherein the forward power detector and the reverse power detector have a same detection gain.

11. The RF module of claim 1 further comprising a second PA and a second bias circuit configured to provide a second DC supply to the second PA, wherein the protection structure is also coupled between the second PA and the second bias circuit.

12. The RF module of claim 11 wherein:
the protection structure is configured to generate the detector voltage by sensing the reverse power reflected from the antenna back to both the first PA and the second PA; and
the protection structure is configured to control the second bias circuit to reduce a second DC supply to the second PA based on the comparison result between the detector voltage and the threshold voltage.

13. The RF module of claim 12 wherein the threshold voltage indicates a maximum value that the reverse power is allowed.

14. The RF module of claim 12 wherein:
the protection structure includes a directional coupler, a reverse power detector, a protection Opamp, the first protection controller, and a second protection controller;
combination of the directional coupler and the reverse power detector is configured to sense the reverse power reflected from the antenna back to both the first PA and the second PA, wherein the detector voltage is an output of the reverse power detector;
the protection Opamp is configured to compare the detector voltage and the threshold voltage;
the first protection controller is configured to control the first bias circuit to reduce the first DC supply to the first PA based on the comparison result; and
the second protection controller is configured to control the second bias circuit to reduce the second DC supply to the second PA based on the comparison result.

15. The RF module of claim 14 wherein:
the first protection controller is implemented by one or more FETs and configured to control the first bias circuit by injecting current into the first bias circuit; and
the second protection controller is implemented by one or more FETs and configured to control the second bias circuit by injecting current into the second bias circuit.

16. The RF module of claim 12 wherein the protection structure is configured to generate the detector voltage further by sensing forward power delivered to the antenna from both the first PA and the second PA.

17. The RF module of claim 16 wherein the threshold voltage indicates a maximum value that a sum of the reverse power and the forward power is allowed.

18. The RF module of claim 16 wherein:
the protection structure includes a directional coupler, a reverse power detector, a forward power detector, a protection Opamp, the first protection controller, and a second protection controller;
a combination of the directional coupler, the forward power detector, and the reverse power detector is configured to sense the forward power delivered to the antenna from both the first PA and the second PA and the reverse power reflected from the antenna back to both the first PA and the second PA, wherein the detector voltage is a sum of an output of the forward power detector and the output of the reverse power detector;
the protection Opamp is configured to compare the detector voltage and the threshold voltage;
the first protection controller is configured to control the first bias circuit to reduce the first DC supply to the first PA based on the comparison result; and
the second protection controller is configured to control the second bias circuit to reduce the second DC supply to the second PA based on the comparison result.

19. The RF module of claim 18 wherein the forward power detector and the reverse power detector have different detection gains.

20. The RF module of claim 19 wherein the reverse power detector has a greater detection gain than the forward power detector.

21. The RF module of claim 18 wherein the forward power detector and the reverse power detector have a same detection gain.
